(19) United States
(12) Patent Application Publication
(10) Pub. No.: US 2017/0022603 A1
(43) Pub. Date: Jan. 26, 2017

(54) BORON-DOPED N-TYPE SILICON TARGET

(71) Applicant: Tosoh SMD, Inc., Grove City, OH (US)

(72) Inventors: Eugene Y. Ivanov, Grove City, OH (US); Yongwen Yuan, Dublin, OH (US)

(21) Appl. No.: 15/300,856

(22) PCT Filed: Mar. 18, 2015
(86) PCT No.: PCT/US2015/021239

§ 371 Date: Sep. 30, 2016

Related U.S. Application Data
(60) Provisional application No. 61/976,094, filed on Apr. 7, 2014.

(51) Int. Cl. C23C 14/34; H01J 37/34; C30B 29/06; C30B 33/00; C23C 14/14; C30B 15/04

(52) U.S. Cl. CPC C23C 14/3414; C23C 14/14; C30B 15/04; C30B 29/06; C30B 33/00; H01J 37/3426; H01J 2237/332

(57) ABSTRACT

Sputter targets and methods of making same. The targets comprise B doped n-type Si. The targets may be made from single crystal boron doped p-type Si ingot made by the CZ method. Resistivities along the length of the crystal are measured, and blanks may be cut perpendicular to the ingot central axis at locations having resistivities of from about 1-20 ohm.cm. The blanks are then formed to acceptable shapes suitable for usage as sputter targets in PVD systems. No donor killing annealing is performed on the ingot or blanks.

### CROSS-REFERENCE TO RELATE APPLICATION

This application claims the priority benefit of U.S. Provisional Patent Application Ser. No. 61/976,094 filed Apr. 7, 2014.

### FIELD OF THE INVENTION

The present application pertains to sputtering targets for forming a silicon containing film and to methods of making such targets.

### BACKGROUND

PVD deposition of a variety of Si films is important in the semiconductor, electronics, and photovoltaic application fields. Accurate film composition and deposition uniformity are important in these fields and others. In many cases, ultrapure monocrystalline Si sputter targets are used in either direct sputter systems such as to form pure Si or Si doped wafers, or the Si targets may be used in reactive sputtering systems to form desired silicon oxide, silicon oxynitride, or silicon nitride films.

Target life using p-type silicon is short. During sputtering of a p-type silicon target, there is re-deposition of silicon product on the target surface with high resistivity. This re-deposit material is amorphous silicon layer with n-type conductivity. This undesirable redeposition is shown schematically in FIG. 1. The following table indicates target re-deposit location, conductivity type of the redeposit, and other measured parameters.

| | Input Current | Output Voltage | Specific Rs | Conductivity |
|---|---|---|---|---|
| Location | (mAdc) | (mVdc) | (ohm cm) | type |
| A | 1 | 221 | 174 | n |
| B | 1 | 45.75 | 36 | p |
| C | 1 | 46.80 | 37 | p |
| D | 1 | 384 | 302 | n |
| E | 1 | 823 | 647 | n |
| F | 1 | 649 | 510 | n |
| G | 1 | 611 | 480 | n |
| H | 1 | 646 | 507 | n |
| I | 1 | 677 | 532 | n |

This redeposition creates p-n junctions on the target surface, which under bias results in the presence of stress in the target, leading to target cracking, thus decreasing target life. Accordingly, it is desirable to minimize the formation of p-n junctions on the target surface by the use of certain n-type Si targets.

### SUMMARY OF THE INVENTION

In one exemplary embodiment of the invention, a sputter target is provided that comprises a B doped N-type Si having a resistivity of about 0.01-700 ohm.cm. In other embodiments, the resistivity of the targets is about 1-12 ohm.cm. In some embodiments, the Si has an oxygen content of about 0.1 to about 200 ppm, and in other embodiments, the oxygen content may be from about 1 to about 60 ppm. In certain embodiments, the boron content of the target is from about 0.01 to about 1 ppm.

Other aspects of the invention comprise sputter targets that are made by obtaining single crystal ingots of B doped p-type Si having resistivity of about 1-60 ohm.cm comprising, measuring the resistivity of the ingot at least at one location along the length of the ingot. Blanks are then formed or sliced from the ingot at those ingot locations that have resistivity within the range of about 1-20 ohm.cm. The chosen blanks are not further heat treated at temperatures of about 400° C. and higher. The blanks are then formed into shapes desirable for use as sputter targets. In other embodiments, the blanks that are selected will have resistivities of about 1-12 ohm.cm.

In yet other embodiments of the invention, methods of making B doped p-type silicon sputter targets are provided. In accordance with these methods, a single crystal Si ingot comprising boron is prepared by the CZ method. The ingot is provided with a central axis that extends along the ingot length. Resistivities of the ingot are measured, and wherein the resistivity as measured is from about 1-20 ohm.cm, blanks are cut from the ingot. Preferably, these blanks are cut perpendicularly to the central axis of the ingot. Then, desired shapes are imparted to the blanks so that they may be useful as sputtering targets. The method is further characterized by being devoid of any heat treatment of the ingot at 400° C. and higher after the ingot has been prepared. In still further embodiments, the resistivity of the cut blanks is about 1-12 ohm.cm.

The invention will be described further in conjunction with the appended drawings and following detailed description of preferred embodiments.

### BRIEF DESCRIPTION OF THE DRAWINGS

FIG. 1 is a schematic representation showing undesirable redeposit formation on a conventional p-type Si sputter target;

FIG. 2 is a schematic illustration showing the effect of oxygen thermal donors in silicon ingot material; and

FIG. 3 is a graph showing resistivity data for n-type and p-type portions of an ingot before annealing and after DK (oxygen donor killing) annealing.

### DETAILED DESCRIPTION OF PREFERRED EMBODIMENTS

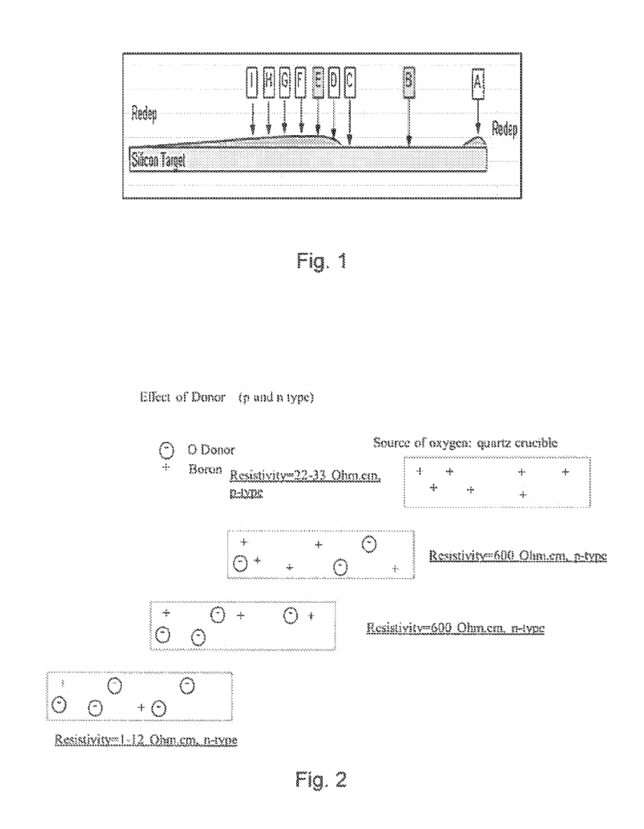

During growing of a high resistivity Czochralski (CZ) silicon ingots (1-100 ohm.cm range), there is certain amount of interstitial oxygen incorporated and formed oxygen thermal donors in silicon ingot material during crystal growth from silica crucible. The formation of oxygen thermal donors depends strongly on both interstitial oxygen concentration which is determined by process temperature and equilibrium between solid silica, liquid silicon, and solid silicon. To provide a certain silicon single crystal resistivity (1-100 ohm.cm), a certain amount of boron dopant is added to silicon. This added boron provides p-type carriers and determines p-type nature of silicon conductivity. The oxygen thermal donors contribute electrons to conduction. Depending on the number of donors generated and the amount of p-type carriers, the background carrier (boron) silicon may be of n-type (more n-type carriers) or p-type (more p-type carriers). In p-type silicon, oxygen thermal donors increase the resistivity of the silicon until the thermal donor concentration exceeds the p-type carrier concentration (boron), at which point the silicon will appear to be n-type. An explanation based on experimental data illustrating the influence of thermal donors on a 22-33 ohm.cm p-type silicon typically used for these targets, and resistivity for varying interstitial oxygen levels and 400° C. annealing times are schematically shown in FIG. 2.

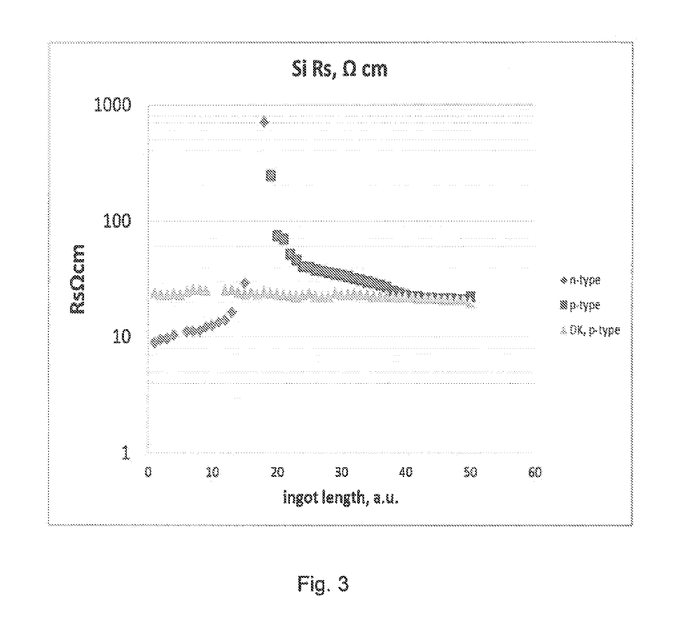

During CZ silicon single crystal growth, some portion of the silicon ingot appears to be n-type conductivity and other portion of silicon ingot is p-type conductivity. It is more reliable to measure resistivity of the silicon single crystal, so we demonstrate actual measurement of silicon single crystal resistivity and conductivity type respectively in the drawing appearing as FIG. 3. This figure shows that before a donor killing (DK) anneal, silicon resistivity is determined by a combination of p and n-type carriers, and after DK anneal, silicon resistivity is only determined by positive carriers according to boron concentration.

In the exemplary embodiments, the invention relates to:

1. Silicon single crystal boron doped material with n-type conductivity resulting from un-annealed oxygen donors with resistivity range from 0.01 to 700 ohm.cm, preferably from 1-12 ohm.cm.

2. Method of manufacturing of Silicon single crystal boron doped material with n-type conductivity resulting from un-annealed oxygen donors, consisting of growing conditions allowed to preserve oxygen donors by avoiding donor killing anneal at 300-800° C.

3. Long life Silicon target single crystal boron doped material with n-type conductivity resulting from un-annealed oxygen donors.

In one embodiment, a sputter target is provided that is a B doped n-type silicon. The B content of the target is typically from about 0.001 to 1 ppm, and the resistivity is from about 1 to 700 ohm.cm. Most preferably, the resistivity is from about 1-20 ohm cm with an even more preferred resistivity ranging from about 1-12 ohm cm.

Although the applicant is not to be bound to any particular theories of operability, it is thought that the amount of interstitial oxygen in the silicon matrix acts as thermal donors to supply the n-type of conductivity. In this regard, the oxygen content of the Si may ranges from about 0.1 to 200 ppm, with a range of 1 to 60 ppm preferred.

Targets in accordance with the method can be produced from Si single crystal ingots that have been prepared by traditional CZ methods involving an initial silicon melt adapted to provide B doped p-type single crystal silicon having a resistivity of about 1-60 ohm.cm, preferably about 22-33 ohm.cm. Traditional CZ methods are shown for example in U.S. Pat. No. 8,961,685 incorporated by reference herein. In typical CZ methods, the Si and B dopant are melted into a quartz crucible or the like. A rod mounted seed crystal is immersed into the melt and is slowly pulled upwards and simultaneously rotated. The process is usually conducted in an inert atmosphere such as argon.

Once the ingot is obtained, it is not subjected to any anneal treatment. Instead, discs or blanks are cut from the ingot and the resistivity measured so that same falls within the ranges above given. The disc or blank is then formed into the desired net shape so that it may be used as a sputter target in physical vapor deposition matters.

While the foregoing is directed to specific embodiments of the invention, other and further embodiments of the invention may be devised without departing from the scope being determined by the appended claims.

What is claimed is:

1. Sputter target comprising B doped n-type Si having a resistivity of about 0.01-700 ohm.cm.

2. Sputter target as recited in claim 1 wherein said resistivity is about 1-20 ohm.cm.

3. Sputter target as recited in claim 2 wherein said resistivity is about 1-12 ohm.cm.

4. Sputter target as recited in claim 1 wherein said Si has an oxygen content of about 0.1 to about 200 ppm.

5. Sputter target as recited in claim 4 wherein said Si has an oxygen content of about 1 to about 60 ppm.

6. Sputter target as recited in claim 1 having a B content of about 0.001 to 1 ppm.

7. Sputter target made by obtaining single crystal ingot of B doped p-type Si having a resistivity of about 1-60 ohm.cm comprising forming blanks from said ingot, measuring the resistivity of said blanks, selecting blanks having resistivities of from about 1-20 ohm.cm, said selected blanks not being further heat treated at temperatures of about 400° C. and higher, and forming said blanks into shapes suitable for use as a sputter target.

8. Sputter target as recited in claim 7 wherein said step of selecting blanks comprises selecting blanks having resistivities of about 1-12 ohm.cm.

9. Method of making a B-doped p-typed Si sputter target comprising:
a) obtaining a single crystal Si ingot comprising B prepared by the CZ method, said ingot having a central axis,
b) measuring resistivities of said ingot at at least one location along said central axis,
c) determining locations along said central axis wherein the resistivity is from about 1-20 ohm. cm,
d) cutting blanks from said ingot at said determined locations (c), and
e) imparting desired shapes to said blanks suitable for use as sputtering targets, wherein said method is devoid of heat treatment of 400° C. and higher after said step (a).

10. Method as recited in claim 9 wherein said step (c) comprises determining locations having resistivity of between about 1-12 ohm.cm.
